(19) United States
(12) Patent Application Publication
(10) Pub. No.: US 2026/0006945 A1
(43) Pub. Date: Jan. 1, 2026

(54) METHOD OF MANUFACTURING DISPLAY APPARATUS AND DISPLAY APPARATUS MANUFACTURED THEREBY

(71) Applicant: KOREA ADVANCED NANO FAB CENTER, Suwon-si, Gyeonggi-do (KR)

(72) Inventors: Hae-Yong JEONG, Yongin-si (KR); Chan Soo SHIN, Yongin-si (KR); Hyeong Ho PARK, Daejeon (KR); Shin Keun KIM, Yongin-si (KR)

(73) Assignee: KOREA ADVANCED NANO FAB CENTER, Suwon-si, Gyeonggi-do (KR)

(21) Appl. No.: 19/132,176

(22) PCT Filed: Oct. 11, 2023
(86) PCT No.: PCT/KR2023/015603

§ 371 Date: May 22, 2025

(30) Foreign Application Priority Data
Nov. 25, 2022 (KR) 10-2022-0160384

(51) Int. Cl. H10H 20/01; H10H 20/821; H10H 29/01; H10H 29/02

(52) U.S. Cl. CPC H10H 20/017; H10H 20/821; H10H 29/02; H10H 29/032

(57) ABSTRACT

Disclosed are a method of manufacturing a display apparatus and a display apparatus manufactured thereby, wherein the method of manufacturing the display apparatus includes a step of forming a T-shaped light-emitting rod including a first conductive semiconductor layer, an active layer, and a second conductive semiconductor layer, a step of laying and aligning the T-shaped light-emitting rod on a control substrate in a lateral direction (├), and a step of forming a first electrode connected to the first conductive semiconductor layer of the aligned T-shaped light-emitting rod, forming a second electrode connected to the second conductive semiconductor layer, and connecting the first electrode and the second electrode to contact electrodes on the control substrate, respectively.

### CROSS REFERENCE TO RELATED APPLICATIONS

This application is a National Stage of International Application No. PCT/KR2023/015603 filed Oct. 11, 2023, claiming priority based on Korean Patent Application No. 10-2022-0160384 filed Nov. 25, 2022.

### TECHNICAL FIELD

The present invention relates to a method of manufacturing a display apparatus and a display apparatus manufactured thereby, and more particularly to a method of manufacturing a display apparatus capable of easily performing arrangement and fixation on a control substrate for display and a display apparatus manufactured thereby.

A Korean national project supported by Korean government associated with this invention is described below.
Project Unique Number: 1711173218
Project Serial Number: 2022M3H4A3085248
Government Department: Ministry of Science and ICT
Specialized Institution for Project Management: National Research Foundation of Korea
Title of Research Business: Nanomaterial Technology Development
Title of Project: Development of 6-inch class LiTaO₃ on Si heterojunction wafer for high frequency filters
Contribution Rate: 1
Supervising Institute: Korea Advanced Fab Center
Research Period: 2023.01.01 to 2023.12.31

### BACKGROUND ART

Due to the high integration and high performance of electrical and electronic apparatuses, various attempts are being made to develop methods of manufacturing a microscopic light-emitting device such as a micro-light-emitting diode or a nano-light-emitting diode.

Typically, in such a light-emitting device, a semiconductor layer is epitaxially grown on a substrate in a planar shape, an electrode is formed, and the same is transferred to a target substrate or a control substrate for display and bonded or fixed thereto.

When such an ultra-small light-emitting device is used as a display light source, especially for implementation of a full-color display, technology for transferring a large number of ultra-small light-emitting devices to a control substrate or a target substrate at high speed and integrating the same is required.

In Korean Patent Application No. 2011-0040925 (Full-color LED display apparatus and method of manufacturing the same), which is a prior art document, an ultra-small LED device is coupled to an electrode in three dimensions in an upright state to implement a display apparatus, wherein a coupling linker is provided under the ultra-small LED device and fine metal powder is added therebetween such that the ultra-small LED device can be easily coupled to the electrode in three dimensions.

That is, an electrode surface of the ultra-small LED device is coated with a coupling linker (first linker) for self-assembly, a second linker capable of being coupled to the coupling linker is formed at a pixel position of an LED display substrate corresponding thereto, the linkers are attached to: metal powder, and heat treatment is performed, whereby the fine metal powder is guided to an ohmic contact layer to fix the LED device at the pixel position of the display substrate.

The above prior art document solves the problem that the ultra-small LED device is lying down or flipped over at the pixel position of the display substrate by the coupling linker for self-assembly.

In the prior art document, however, the coupling linkers are formed on the electrode surface of the LED device and at the pixel position of the display substrate, the fine metal powder is added, and soldering is performed, which are very cumbersome processes, and there is a concern that surrounding devices may be damaged during the coupling process.

In addition, since coupling is chemically induced by self-assembly, it is very difficult to coupling the ultra-small LED device to the electrode in three dimensions in an upright state, and there is a high risk of pixel defects due to the high possibility that process variables will come into play.

In addition, if only one micro-scale LED is used per pixel, defective LEDs may simultaneously cause pixel defects.

Furthermore, as a sub-pixel formed in the display is located on the electrode, even if the nano-scale ultra-small LED is connected to the electrode in three dimensions in an upright state, light extraction from photons generated in an active layer of the ultra-small LED device may not be perfectly performed, and there is a concern that the light extraction is degraded by total reflection at the interface between the surface of the upright ultra-small LED and an air layer.

Moreover, there is the problem that light extraction efficiency to the outside is not high because the light is blocked by the electrode at the upper end and the light extraction efficiency is reduced as part of the light is absorbed in the active layer.

### DISCLOSURE

### Technical Problem

The present invention has been conceived to address the above needs, and it is an object of the present invention to provide a method of manufacturing a display apparatus capable of forming a T-shaped light-emitting rod and easily performing selective array and fixation of the same at a specific position on a control substrate for display and a display apparatus manufactured thereby.

### Technical Solution

A technical gist of the present invention to accomplish the above object is a method of manufacturing a display apparatus, the method including a step of forming a T-shaped light-emitting rod including a first conductive semiconductor layer, an active layer, and a second conductive semiconductor layer, a step of laying and aligning the T-shaped light-emitting rod on a control substrate in a lateral direction (├), and a step of forming a first electrode connected to the first conductive semiconductor layer of the aligned T-shaped light-emitting rod, forming a second electrode connected to the second conductive semiconductor layer, and connecting the first electrode and the second electrode to contact electrodes on the control substrate, respectively.

In addition, the step of forming the T-shaped light-emitting rod may include forming a sacrificial layer on a growth substrate, forming a first conductive semiconductor layer on the sacrificial layer, forming a rod pattern through selective etching or selective growth by patterning of the first conductive semiconductor layer, forming an active layer so as to surround the first conductive semiconductor layer and the rod pattern, forming a second conductive semiconductor layer so as to surround the active layer, mesa-etching the second conductive semiconductor layer, the active layer, and the first conductive semiconductor layer between the rod pattern, and removing the sacrificial layer and separating the first conductive semiconductor layer from the growth substrate to form a T-shaped light-emitting rod.

In addition, the step of forming the rod pattern may be performed by a mask patterning process of the first conductive semiconductor layer.

In addition, the mask patterning process may include forming a mask pattern on the first conductive semiconductor layer and forming the rod pattern in a top-down manner using the same as an etching mask. In addition, the mask patterning process may include forming a mask pattern on the first conductive semiconductor layer and forming the rod pattern in a bottom-up manner using the same as a deposition mask.

In addition, the method may further include forming a first insulating layer on the sacrificial layer and the second conductive semiconductor layer after the mesa-etching step and etching the first insulating layer on the sacrificial layer.

In addition, the step of forming the T-shaped light-emitting rod may include forming a sacrificial layer on a growth substrate, forming a first conductive semiconductor layer on the sacrificial layer, forming an active layer on the first conductive semiconductor layer, forming a second conductive semiconductor layer on the active layer, forming a rod pattern including the second conductive semiconductor layer and the active layer by a mask patterning process, mesa-etching the first conductive semiconductor layer between the rod pattern, and removing the sacrificial layer and separating the first conductive semiconductor layer from the growth substrate to form a T-shaped light-emitting rod.

In addition, the method may further include forming a first insulating layer on the sacrificial layer and the rod pattern after the mesa-etching step and etching the first insulating layer formed on the sacrificial layer.

In addition, the step of laying and aligning the T-shaped light-emitting rod on the control substrate in the lateral direction may include forming a second insulating layer on the control substrate comprising the contact electrodes, forming a coupling recess in the second insulating layer such that the T-shaped light-emitting rod can be laid and aligned in the lateral direction, and aligning the T-shaped light-emitting rod in the coupling recess.

In addition, coupling surfaces of the T-shaped light-emitting rod and the coupling recess may be surface-modified so as to be mutually stably coupled to each other.

In addition, the step of connecting the first electrode and the second electrode to the contact electrodes on the control substrate, respectively, may include etching the second insulating layer to expose electrode contact portions of the first conductive semiconductor layer and the second conductive semiconductor layer, insulating the first conductive semiconductor layer and the second conductive semiconductor layer from each other, and forming the first electrode and the second electrode and connecting the first electrode and the second electrode to the contact electrodes on the control substrate, respectively.

In addition, the step of laying and aligning the T-shaped light-emitting rod on the control substrate in the lateral direction may include a first process of forming a second insulating layer on the control substrate including the contact electrodes, forming a first coupling recess in the second insulating layer such that a first T-shaped light-emitting rod can be aligned in the lateral direction, and aligning the first T-shaped light-emitting rod in the first coupling recess, a second process of shielding the first T-shaped light-emitting rod with the second insulating layer, forming a second coupling recess in an adjacent region, and aligning a second T-shaped light-emitting rod having a different active layer from the first T-shaped light-emitting rod in the second coupling recess, and a third process of shielding the second T-shaped light-emitting rod with the second insulating layer, forming a third coupling recess in an adjacent region, and aligning a third T-shaped light-emitting rod having a different active layer from the first and second T-shaped light-emitting rods in the third coupling recess, whereby pluralities of first, second, and third T-shaped light-emitting rods having different emission wavelengths may be simultaneously aligned on the control substrate by the first process, the second process, and the third process, respectively.

In addition, the step of connecting the first electrode and the second electrode to the contact electrodes on the control substrate, respectively, may include etching the second insulating layer to simultaneously expose electrode contact portions of first conductive semiconductor layers and second conductive semiconductor layers of the first, second, and third T-shaped d light-emitting rods, insulating the first conductive semiconductor layer and the second conductive semiconductor layer from each other, and forming the first electrode and the second electrode and connecting the first electrode and the second electrode to the contact electrodes on the control substrate, respectively.

In addition, the first, second, and third T-shaped light-emitting rods may be aligned on the control substrate in a linear array in the same direction, may be aligned on the control substrate in a linear array in opposite directions, or may be aligned radially on the control substrate.

In addition, coupling surfaces of the T-shaped light-emitting rod and the coupling recess may be surface-modified so as to be mutually stably coupled to each other.

Another technical gist of the present invention is a display apparatus including a control substrate including contact electrodes, an insulating layer formed on the control substrate, the insulating layer including a coupling recess, a T-shaped light-emitting rod received in the coupling recess and laid and aligned in a lateral direction, the T-shaped light-emitting rod including a first conductive semiconductor layer, an active layer, and a second conductive semiconductor layer, and a first electrode connected to the first conductive semiconductor layer and a second electrode connected to the second conductive semiconductor layer, the first electrode and the second electrode being connected to the contact electrodes.

In addition, the T-shaped light-emitting rod may be provided in plural such that each of the T-shaped light-emitting rods is aligned in the coupling recess, and the T-shaped light-emitting rods may include active layers having the same emission wavelength or different emission wavelengths.

Here, the T-shaped light-emitting rods may be aligned on the control substrate in a linear array in the same direction, may be aligned on the control substrate in a linear array in opposite directions, or may be aligned radially on the control substrate.

In addition, a lens portion may be further formed on the T-shaped light-emitting rod.

### Advantageous Effects

The present invention provides a display apparatus configured by manufacturing a T-shaped light-emitting rod, aligning the same on a control substrate in a lateral direction, and forming an electrode, wherein ultra-small T-shaped light-emitting rods may be easily aligned on the control substrate for display in large quantities, light emission efficiency is increased, and selective array and fixation of the T-shaped light-emitting rods at a specific position on the control substrate are easily performed.

Also, in the present invention, predetermined coupling recesses are formed in the control substrate for display such that the T-shaped light-emitting rods can be advantageously aligned and fixed in a lateral direction, rather than being coupled in a forward or reverse direction, whereby accurate and large-scale alignment of ultra-small T-shaped light-emitting rods may be quickly performed, resulting in high process yield and minimized pixel defects.

Also, in the present invention, alignment of T-shaped light-emitting rods having multiple emission wavelengths for implementation of a full-color display apparatus may be accurately and quickly performed by sequentially forming coupling recesses corresponding to emission wavelengths, aligning T-shaped light-emitting rods having respective emission wavelengths, and simultaneously forming electrodes.

### DESCRIPTION OF DRAWINGS

FIGS. 1A, 1B, 1C, 1D, 1E, 1F, 1G, 1H, 11, 2A, 2B, 2C, 2D, 2E, 2F, 2G, 2H, and 2I are schematic views showing a method of manufacturing a T-shaped light-emitting rod according to an embodiment of the present invention.

FIGS. 3A, 3B, 3C, 3D, and 3E are schematic views showing a method of manufacturing a display apparatus according to the embodiment shown in FIGS. 1A, 1B, 1C, 1D, 1E, 1F, 1G, 1H, 11, 2A, 2B, 2C, 2D, 2E, 2F, 2G, 2H, and 2I.

FIGS. 4A, 4B, 4C, 4D, and 4E are schematic views showing a method of manufacturing a T-shaped light-emitting rod according to another embodiment of the present invention.

FIG. 5 is a schematic view showing a display apparatus according to the embodiment shown in FIGS. 4A, 4B, 4C, 4D, and 4E.

FIGS. 6A, 6B, 6C, 6D, and 6E are schematic views showing a method of manufacturing a display apparatus having various emission wavelengths according to an embodiment of the present invention.

FIGS. 7A, 7B, 8A, 8B, and 9 are schematic views showing display apparatuses according to various embodiments of the present invention.

### BEST MODE

Advantages and features of the present invention and a method of achieving the same will be more clearly understood from embodiments described below with reference to the accompanying drawings. However, the present invention is not limited to the following embodiments and may be implemented in various different forms. The embodiments are provided merely to complete the present invention and to fully provide a person having ordinary skill in the art to which the present invention pertains with the category of the present invention, and the present invention is defined only by the category of the claims. Throughout the specification, the same reference numerals refer to the same components.

When a device or layer is referred to as being “on” or “above” another device or layer, this includes both the case in which the device or layer is located directly above the other device or layer and the case in which a further layer or device is interposed therebetween. On the other hand, when a device is referred to as “directly on” or “directly above” another device, this means that there is no further device or layer therebetween.

Spatially relative terms such as “below,” “beneath,” “lower,” “above,” or “upper” may be used herein to easily describe correlation between a device or component and another device or component as shown in the drawings. It will be understood that spatially relative terms are intended to encompass different orientations of a device during use or operation of the device in addition to the orientation shown in the drawings. For example, if devices shown in the drawings are turned over, a device described as “below” or “beneath” another device would then be oriented “above” the other device. Therefore, the exemplary term “below” or “beneath” may encompass both orientations of above and below. The device may be oriented in another direction, in which case spatially relative terms may be interpreted in accordance with the orientation.

The terms used in this specification are provided only to explain embodiments, but are not intended to restrict the present invention. In this specification, a singular representation may include a plural representation unless mentioned otherwise. It will be further understood that the terms “comprises” and/or “comprising,” when used in this specification, specify the presence of stated elements, steps, operations, and/or devices, but do not preclude the presence or addition of one or more other elements, steps, operations, and/or devices.

Unless otherwise defined, all terms (including technical and scientific terms) used in this specification have the same meaning as commonly understood by a person having ordinary skill in the art to which the present invention pertains. It will be further understood that terms, such as those defined in commonly used dictionaries, will not be interpreted in an idealized or overly formal sense unless expressly so defined herein.

The present invention provides a display apparatus configured by forming a T-shaped light-emitting rod and aligning the same on a control substrate for display.

Particularly, in order to align the T-shaped light-emitting rod on the control substrate for display, a coupling recess having a predetermined shape is formed in the control substrate, and the T-shaped light-emitting rod is coupled to the coupling recess, whereby it is easy to selectively array and fix the T-shaped light-emitting rod at a specific position on the control substrate for display.

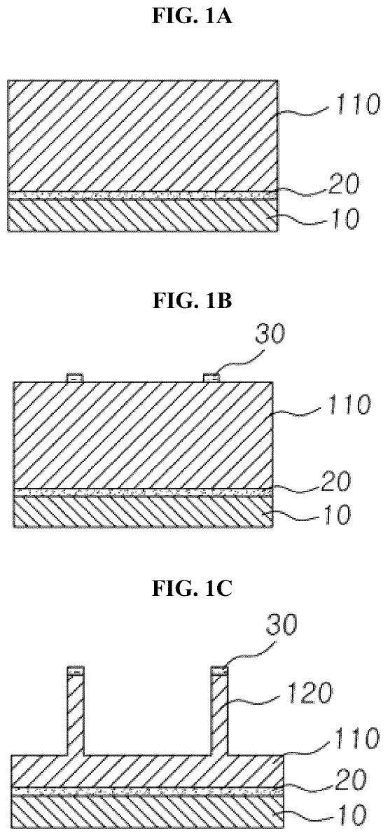

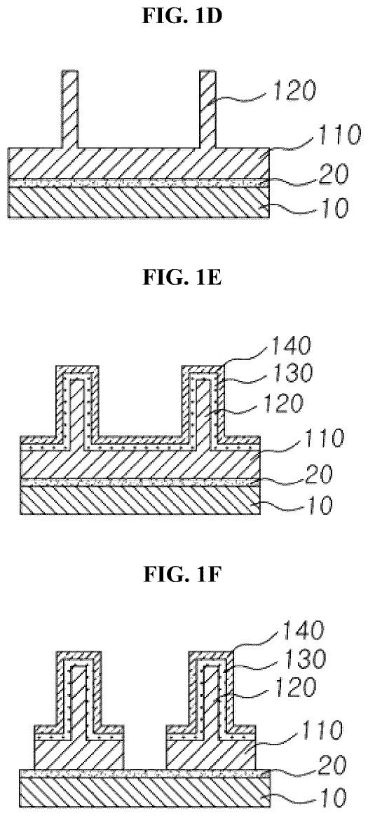

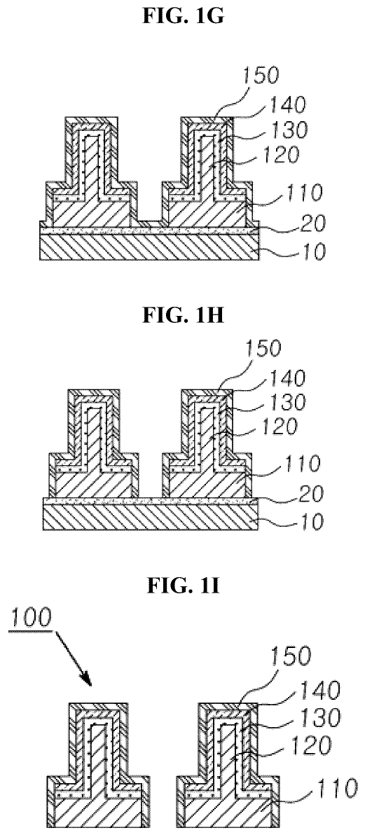

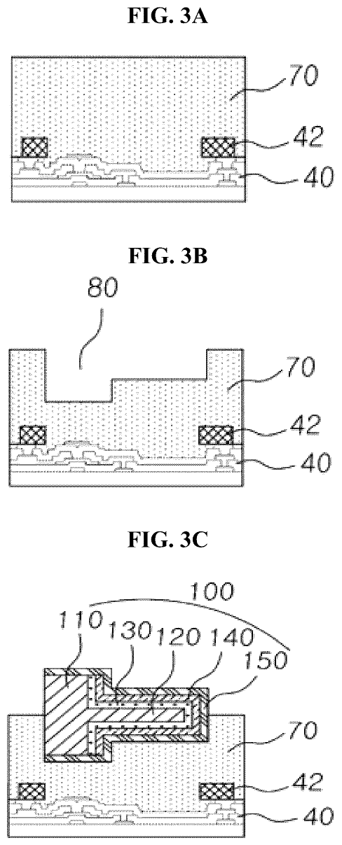

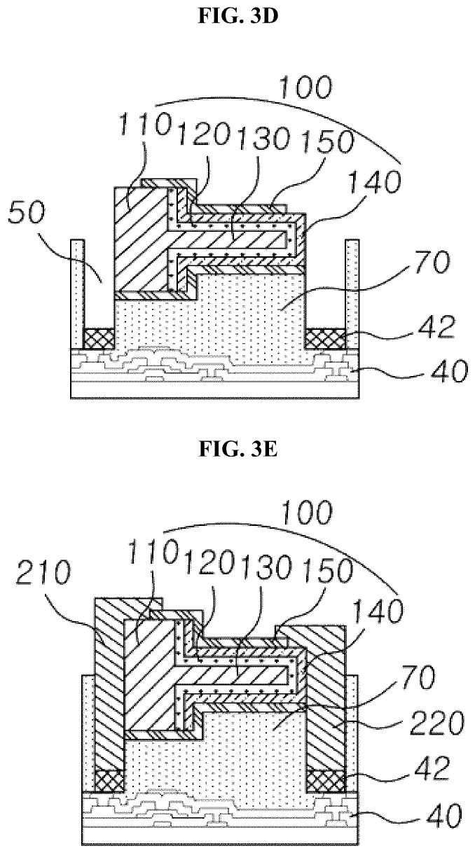

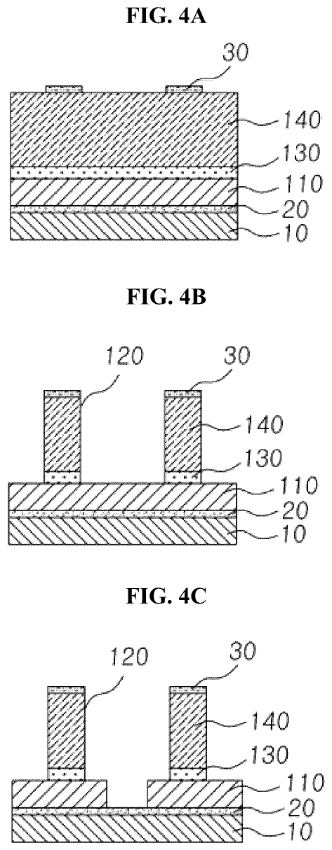

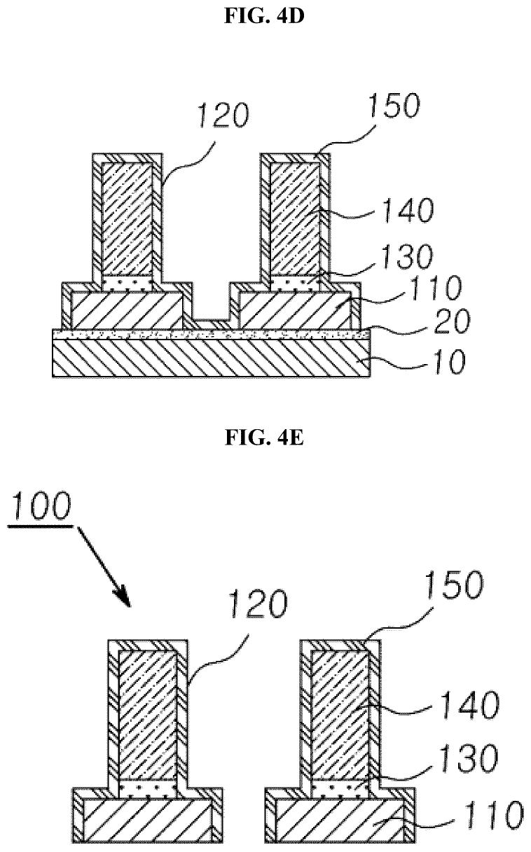

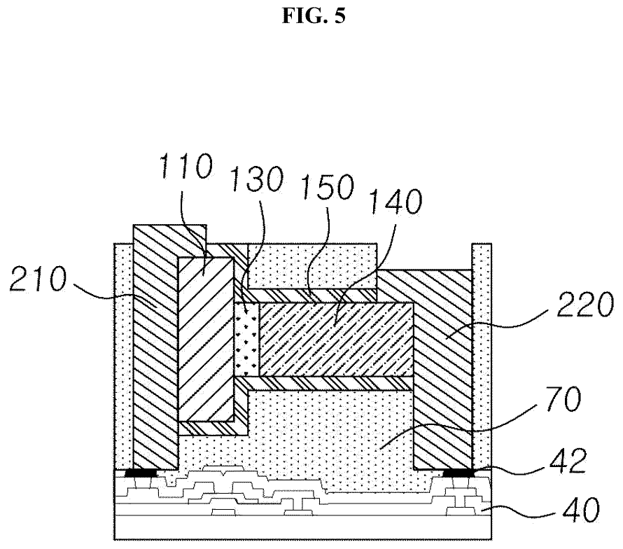

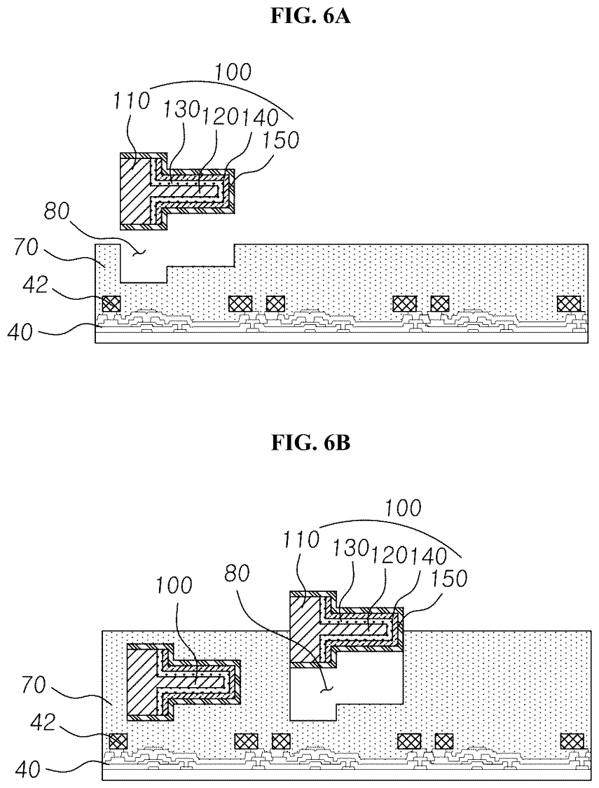

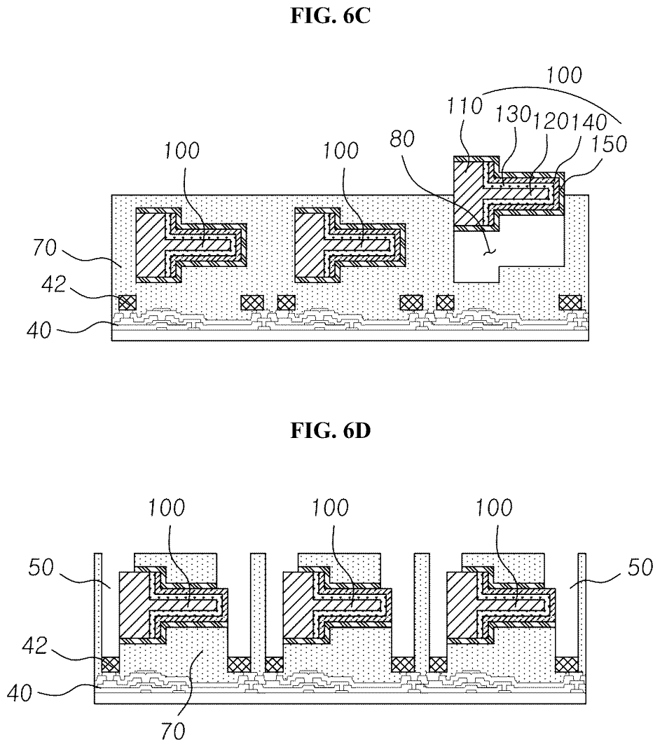

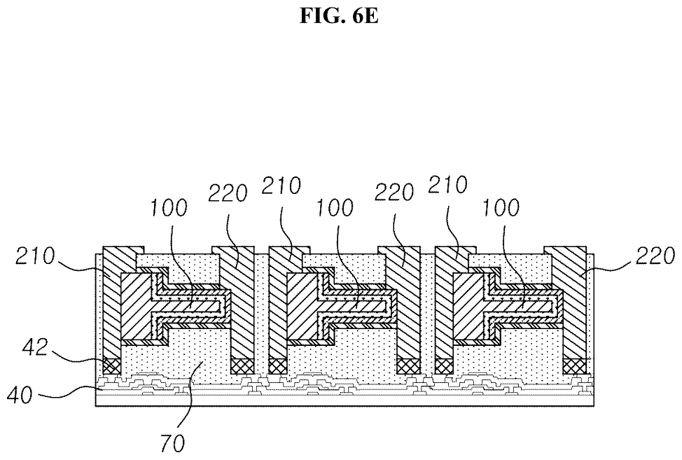

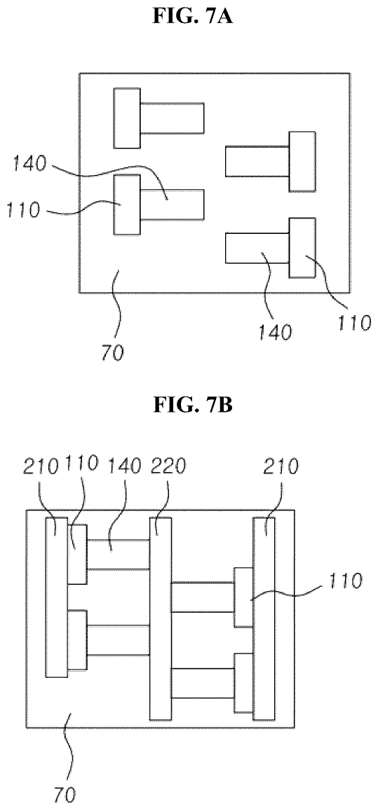

Hereinafter, embodiments of the present invention will be described in detail with reference to the accompanying drawings. FIGS. 1A, 1B, 1C, 1D, 1E, 1F, 1G, 1H, 11, 2A, 2B, 2C, 2D, 2E, 2F, 2G, 2H, and 2I are schematic views showing a method of manufacturing a T-shaped light-emitting rod according to an embodiment of the present invention, FIGS. 3A, 3B, 3C, 3D, and 3E are schematic views showing a method of manufacturing a display apparatus according to the embodiment shown in FIGS. 1A, 1B, 1C, 1D, 1E, 1F, 1G, 1H, 11, 2A, 2B, 2C, 2D, 2E, 2F, 2G, 2H, and 2I, FIGS. 4A, 4B, 4C, 4D, and 4E are schematic views showing a method of manufacturing a T-shaped light-emitting rod according to another embodiment of the present invention, FIG. 5 is a schematic view showing a display apparatus according to the embodiment shown in FIGS. 4A, 4B, 4C, 4D, and 4E, and FIGS. 6A, 6B, 6C, 6D, and 6E are schematic views showing a method of manufacturing a display apparatus having various emission wavelengths according to an embodiment of the present invention, and FIGS. 7A, 7B, 8A, 8B, and 9 are schematic views showing display apparatuses according to various embodiments of the present invention.

As shown, a method of manufacturing a display apparatus according to an embodiment of the present invention includes a step of forming a T-shaped light-emitting rod including a first conductive semiconductor layer, an active layer, and a second conductive semiconductor layer, a step of laying and aligning the T-shaped light-emitting rod on a control substrate in a lateral direction (├), and a step of forming a first electrode connected to the first conductive semiconductor layer of the aligned T-shaped light-emitting rod, forming a second electrode connected to the second conductive semiconductor layer, and connecting the first electrode and the second electrode to contact electrodes on the control substrate, respectively.

Here, the step of forming the T-shaped light-emitting rod includes a step of forming a sacrificial layer on a growth substrate, a step of forming a first conductive semiconductor layer on the sacrificial layer, a step of etching the first conductive semiconductor layer to a predetermined depth to form a rod pattern, a step of forming an active layer so as to surround the first conductive semiconductor layer and the rod pattern, a step of forming a second conductive semiconductor layer so as to surround the active layer, a step of mesa-etching the second conductive semiconductor layer, the active layer, and the first conductive semiconductor layer between the rod pattern, and a step of removing the sacrificial layer and separating the first conductive semiconductor layer from the growth substrate to form a plurality of T-shaped light-emitting rods.

The T-shaped light-emitting rod thus manufactured is aligned on the control substrate in the lateral direction, and the electrode is formed, whereby the display apparatus according to the present invention is provided, and therefore ultra-small T-shaped light-emitting rods may be easily aligned on the control substrate for display in large quantities, light emission efficiency is increased, and selective array and fixation of the T-shaped light-emitting rods at a specific position on the control substrate are easily performed.

The T-shaped light-emitting rod according to the present invention includes a first conductive semiconductor layer, an active layer, and a second conductive semiconductor layer, and may include various types of semiconductor layers including an active layer.

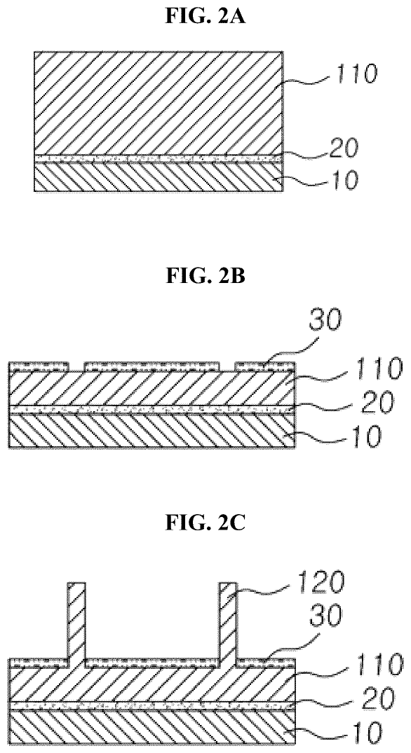

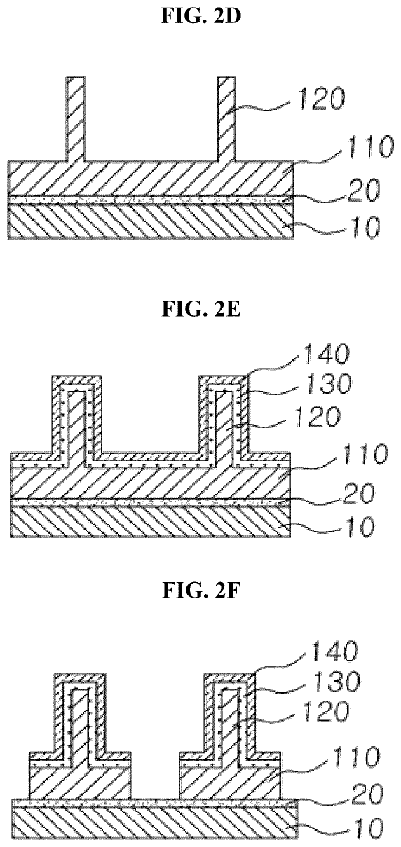

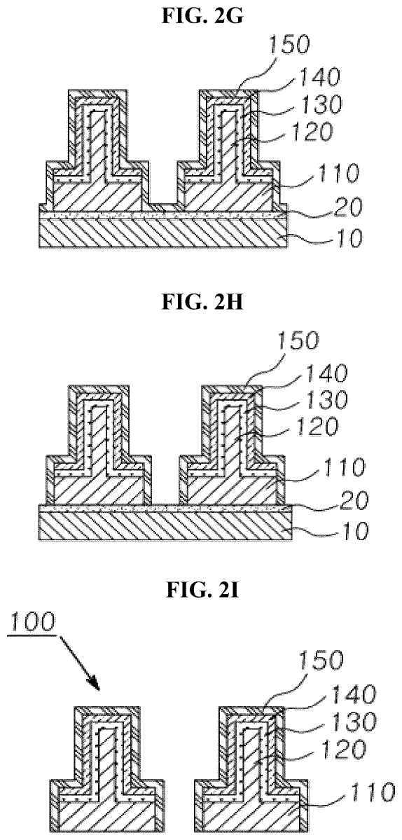

In a method of manufacturing a T-shaped light-emitting rod according to an embodiment of the present invention, firstly, a sacrificial layer is formed on a growth substrate, and a first conductive semiconductor layer is formed on the sacrificial layer (FIGS. 1A and 2A).

Any one of GaN, Zno, Gap, MgAl₂O₄, MgO, LaAlO₂, LaGaO₂, GaAs, AlN, InP, Cu, and a conductive substrate may be used as the growth substrate; however, the present invention is not limited thereto as long as it is possible to epitaxially grow a semiconductor layer.

The sacrificial layer according to the embodiment of the present invention may be separated by depositing or bonding a film that can cause physical stress after growth by remote epitaxy using a 2D material such as graphene.

A III-V, II-V, or IV-V compound semiconductor or a compound semiconductor mixture thereof may be used as the first conductive semiconductor layer according to the present invention.

The first conductive semiconductor layer according to the embodiment of the present invention may be a first-conductivity-type semiconductor, such as an n-type semiconductor. As an example, when the light-emitting device emits blue wavelength light, the first conductive semiconductor layer may include a semiconductor material having the formula InₓAl_{y}Ga_{1-x-y}N (0≤x≤1, 0≤y≤1, 0≤x+y≤1).

For example, at least one of n-type doped InAlGaN, GaN, AlGaN, InGaN, AlN, and InN may be included. The first conductive semiconductor layer may be doped with a first conductive dopant, and as an example, the first conductive dopant may be Si, Ge, or Sn. In an exemplary embodiment, the first conductive semiconductor layer may be n-GaN doped with n-type Si.

Subsequently, a rod pattern is formed through selective etching or selective growth by patterning of the first conductive semiconductor layer (FIGS. 1B, 1C, 2B and 2C).

The rod pattern is formed by a mask patterning process of the first conductive semiconductor layer, and the rod pattern is formed on the first conductive semiconductor layer by selective etching or selective growth using an etching mask or a deposition mask.

The height of the rod pattern in the present invention is within the range of several nanometers to several hundred micrometers, and is formed in consideration of the control substrate for display on which the rod pattern is to be mounted and the light emission area.

The rod pattern corresponds to a T-shaped tail portion of the T-shaped light-emitting rod provided according to the present invention, and a T-shaped head portion corresponds to the planar first conductive semiconductor layer epitaxially grown on the sacrificial layer.

The T-shaped tail portion may be formed in plural with respect to the T-shaped head portion as needed, and may have any of various sectional shapes, such as a circular shape, a polygonal shape, and an elliptical shape. In addition, the T-shaped tail portion may be formed so as to have a trapezoidal shape with a larger bottom width or a larger top width as needed. This may be implemented through control of a growth direction by controlling etching process conditions or deposition process conditions using a mask pattern, a description of which will follow.

According to the embodiment of the present invention, in a mask patterning process for forming the rod pattern, a mask pattern is formed on the first conductive semiconductor layer, and the rod pattern is formed in a top-down manner using the same as an etching mask (FIGS. 1B and 1C).

For example, a photoresist pattern for forming a mask pattern is formed on the first conductive semiconductor layer, a mask pattern is formed at an interval corresponding to the width of the rod pattern, and the first conductive semiconductor layer is selectively etched to a predetermined depth using the same as an etching mask.

Here, the mask pattern may be made of SiO₂, SiN, Al₂O₃, or TiO₂; however, the present invention is not limited thereto. A dry or wet etching method for etching an insulating layer may be used after a general semiconductor process or formation of a photoresist pattern.

For example, dry etching may be performed using a chlorine (Cl₂) or hydrocarbon (CH₄)-based etch gas, and wet etching may be performed using an etchant including sulfuric acid, phosphoric acid, potassium hydroxide, or sodium hydroxide; however, the present invention is not limited thereto.

Since rod-type etching is required in the present invention, a dry etching method capable of performing anisotropic etching is preferred. However, depending on the height or shape of the rod, isotropic etching may be performed. As described above, it is possible to provide rod patterns of various sizes or shapes by controlling the etching process.

Furthermore, in the embodiment of the present invention, an etch stop layer may be added to control the degree of etching when the first conductive semiconductor layer is formed.

In addition, according to the embodiment of the present invention, in the mask patterning process for forming the rod pattern, a mask pattern is formed on the first conductive semiconductor layer, and the rod pattern is formed by selective growth in a bottom-up manner using the same as a deposition mask (FIGS. 2B and 2C).

For example, a photoresist pattern for forming a mask pattern is formed on the first conductive semiconductor layer, a mask pattern is formed at an interval corresponding to the width of the rod pattern, and the first conductive semiconductor layer is selectively grown to a predetermined height using the same as a deposition mask.

Here, the mask pattern may be made of SiO₂, SiN, Al₂O₃, or TiO₂; however, the present invention is not limited thereto. The rod pattern is formed by microfilm regrowth on the first conductive semiconductor layer through a process, such as metalorganic chemical vapor deposition (MOCVD), molecular beam epitaxy (MBE), atomic layer deposition (ALD), focused ion beam (FIB), sputtering, or plating, using the same as a deposition mask.

According to the embodiment of the present invention, a rod pattern made of a first conductive semiconductor is formed by selective etching or selective growth, and the etching mask or the deposition mask is removed, whereby a rod pattern in which a sacrificial layer is formed on a growth substrate and a rod-shaped first conductive semiconductor layer is formed on a planar first conductive semiconductor layer is provided (FIGS. 1D and 2D).

After the rod pattern is formed, an active layer is formed so as to surround the first conductive semiconductor layer and the rod pattern. A second conductive semiconductor layer is formed so as to surround the active layer (FIGS. 1E and 2E).

The second conductive semiconductor layer according to the embodiment of the present invention may be a second conductivity-type semiconductor, such as a p-type semiconductor, and as an example, when the light-emitting device emits blue or green wavelength light, the second conductive semiconductor may include a semiconductor material having the chemical formula InₓAl_{y}Ga_{1-x-y}N (0≤x≤1, 0≤y≤1, 0≤x+y≤1). For example, at least one of p-type doped InAlGaN, GaN, AlGaN, InGaN, AlN, and InN may be included.

The second conductive semiconductor may be doped with a second conductive dopant, and as an example, the second conductive dopant may be Mg, Zn, Ca, Se, or Ba. In an exemplary embodiment, the second conductive semiconductor may be p-GaN doped with p-type Mg.

Meanwhile, each of the first conductive semiconductor layer and the second conductive semiconductor layer are shown as being a single layer in the drawings; however, the present invention is not limited thereto. In some cases, depending on the material of the active layer, each of the first conductive semiconductor layer and the second conductive semiconductor layer may further include a greater number of layers, such as a clad layer or a tensile strain barrier reducing (TSBR) layer.

The active layer may be an active layer having a single layer structure, a multilayer structure, or a multi-quantum well (MQW) structure depending on the emission wavelength. For example, the active layer may have an emission wavelength of blue, green, yellow, or red by appropriately adjusting the composition while adding In to GaN. That is, as the composition of In increases, the active layer has an emission wavelength close to red (long wavelength), and as the composition of In decreases, the active layer has an emission wavelength close to blue (short wavelength).

According to the embodiment of the present invention, the material of the active layer of the multi-quantum well structure is adjusted such that the active layer has a single emission wavelength or multiple emission wavelengths.

The active layer may emit light by coupling of electron-hole pairs in response to an electrical signal applied through the first conductive semiconductor layer and the second conductive semiconductor layer. As an example, when the active layer emits blue wavelength light, the active layer may include a material such as AlGaN or AlInGaN. In particular, when the active layer has a multi-quantum well structure in which quantum layers and well layers are alternately stacked, each quantum layer may include a material such as AlGaN or AlInGaN, and each well layer may include a material such as GaN or AlInN. In an exemplary embodiment, the active layer includes AlGaInN as the quantum layer and AlInN as the well layer, and the active layer may emit blue light having a center wavelength band of 450 nm to 495 nm.

However, the present invention is not limited thereto, and the active layer may have a structure in which semiconductor materials having large band gap energy and semiconductor materials having small band gap energy are alternately stacked, and may include different III to V group semiconductor materials depending on the wavelength band of light that is emitted. The light emitted by the active layer is not limited to blue wavelength light, and in some cases, the active layer may emit red, green, UV, or IR light.

According to the present invention, an active layer is formed along a rod pattern made of a first conductive semiconductor layer, and a second conductive semiconductor layer is formed along the active layer, whereby the first conductive semiconductor layer/active layer/second conductive semiconductor layer are overall formed in the form of a rod, and therefore the light emitted by the active layer is emitted along the upper surface and both side surfaces of the rod and is also emitted to the upper surface of the planar first conductive semiconductor layer, resulting in the light emission area being greater than the light emission area of a conventional planar device.

Subsequently, the second conductive semiconductor layer, the active layer, and the first conductive semiconductor layer between the rod pattern are mesa-etched (FIGS. 1F and 2F). Subsequently, the sacrificial layer is removed and the first conductive semiconductor layer is separated from the growth substrate to form a plurality of T-shaped light-emitting rods (FIGS. 1I and 21).

In the present invention, the planar or rod-shaped first conductive semiconductor layer, the active layer, and the second conductive semiconductor layer are referred to a T-shaped light-emitting rod for the sake of convenience. A rod pattern formed on a large-area growth substrate is formed as a plurality of T-shaped light-emitting rods by inter-pattern mesa etching.

A laser lift-off (LLO) method, a chemical lift-off (CLO) method, or an electrochemical lift-off (ELO) method may be used as a method of separating the T-shaped light-emitting rod from the growth substrate.

In the embodiment of the present invention, the T-shaped light-emitting rod is removed from the growth substrate by removing the sacrificial layer using an etchant by the CLO method. At this time, the etchant selectively etches the sacrificial layer.

Here, a step of forming a first insulating layer on the sacrificial layer and the second conductive semiconductor layer after the mesa-etching process (FIGS. 1G and 2G) and a step of etching the first insulating layer on the sacrificial layer (FIGS. 1H and 2H) may be further included as needed.

The first insulating layer is a kind of electrical and chemical shield for protecting the T-shaped light-emitting rod, and may be SiO₂, SiN, Al₂O₃, or TiO₂ in the embodiment of the present invention; however, the present invention is not limited thereto. The first insulating layer according to the present invention is preferably made of a transparent material due to the structure of the T-shaped light-emitting rod.

After the first insulating layer is formed, the first insulating layer on the sacrificial layer is etched, the sacrificial layer is removed from the growth substrate, and the first conductive semiconductor layer is separated from the growth substrate to form a plurality of T-shaped light-emitting rods (FIGS. 1I and 2I).

Meanwhile, in another embodiment of the present invention, as shown in FIGS. 4A, 4B, 4C, 4D, and 4E, the step of forming the T-shaped light-emitting rod includes a step of forming a sacrificial layer on a growth substrate (FIG. 4A), a step of forming a first conductive semiconductor layer on the sacrificial layer (FIG. 4A), a step of forming an active layer on the first conductive semiconductor layer (FIG. 4A), a step of forming a second conductive semiconductor layer on the active layer (FIG. 4A), a step of forming a rod pattern including the second conductive semiconductor layer and the active layer by a mask patterning process (FIG. 4B), a step of mesa-etching the first conductive semiconductor layer between the rod pattern (FIG. 4C), and a step of removing the sacrificial layer and separating the first conductive semiconductor layer from the growth substrate to form a T-shaped light-emitting rod (FIG. 4E).

That is, in the previous embodiment of the T-shaped light-emitting rod, a first conductive semiconductor layer is formed in the form of a rod, and an active layer and a second conductive semiconductor layer are formed to surround the same, and in the present embodiment, a first conductive semiconductor layer, an active layer, and a second conductive semiconductor layer are stacked in a planar shape, and a T-shaped light-emitting rod is formed by etching through a mask patterning process.

At this time, the etching may be performed such that a part of the first conductive semiconductor layer remains by adjusting the etching process such that the sacrificial layer is not exposed, or the degree of etch may be controlled by adding an etch stop layer when the first conductive semiconductor layer is formed.

Consequently, the rod pattern according to the present invention may be etched such that a part of the first conductive semiconductor layer is included or the second conductive semiconductor layer and the active layer are included (a T-shaped tail portion) and a T-shaped head portion is formed of the first conductive semiconductor layer.

As a result, the light emission area of the T-shaped light-emitting rod according to various embodiments of the present invention may be adjusted by controlling the area or line width of the first conductive semiconductor layer, the active layer, and the second conductive semiconductor layer.

In addition, even in the present embodiment, a step of forming a first insulating layer on the sacrificial layer and the second conductive semiconductor layer after the mesa-etching process (FIG. 4D) and a step of etching the first insulating layer on the sacrificial layer may be further included as needed. After the first insulating layer is formed, the first insulating layer on the sacrificial layer is etched, the sacrificial layer is removed from the growth substrate, and the first conductive semiconductor layer is separated from the growth substrate to form a plurality of T-shaped light-emitting rods (FIG. 4E).

The first insulating layer is a kind of electrical and chemical shield for protecting the T-shaped light-emitting rod, and may be SiO₂, SiN, Al₂O₃, or TiO₂ in the embodiment of the present invention; however, the present invention is not limited thereto.

After the T-shaped light-emitting rod is manufactured as described above, the same is laid and aligned on the control substrate in the lateral direction (H). A first electrode connected to the first conductive semiconductor layer of the aligned T-shaped light-emitting rod is formed, a second electrode connected to the second conductive semiconductor layer is formed to form a T-shaped light-emitting rod structure, and the first electrode and the second electrode are connected to contact electrodes on the control substrate (FIGS. 3A, 3B, 3C, 3D, 3E, 5, 6A, 6B, 6C, 6D, and 6E).

The T-shaped light-emitting rod according to the present invention has different shapes in forward, reverse, and lateral directions, whereby the T-shaped light-emitting rod is aligned in a specific direction as a predetermined coupling recess is formed in the control substrate. According to the embodiment of the present invention, since the rod (the T-shaped tail portion) includes a first conductive semiconductor layer, an active layer, and a second conductive semiconductor layer, or includes an active layer and a second conductive semiconductor layer, it is preferable to lay and align the T-shaped light-emitting rod in the lateral direction for light emission efficiency. Consequently, the coupling recess formed in the control substrate is correspondingly formed such that the T-shaped light-emitting rod is coupled to the coupling recess in the lateral direction.

That is, in the step of laying and aligning the T-shaped light-emitting rod according to the embodiment of the present invention on the control substrate in the lateral direction, a second insulating layer is formed on the control substrate including the contact electrodes (FIG. 3A), a coupling recess is formed in the second insulating layer such that the T-shaped light-emitting rod is laid and aligned in the lateral direction (FIG. 3B), and the T-shaped light-emitting rod is aligned in the coupling recess (FIG. 3C).

The control substrate is a control substrate in which an IC for driving the display apparatus is integrated, and the contact electrodes are formed on the control substrate such that the T-shaped light-emitting rod according to the present invention is electrically connected to the contact electrodes so as to be driven. That is, each contact electrode is constituted by a pair of contacts per pixel (per unit light-emitting device), and is electrically connected to a corresponding one of the first electrode and the second electrode for connection with the T-shaped light-emitting rod according to the present invention. In general, a known control substrate is used as the control substrate on which the contact electrodes are formed.

A second insulating layer is formed on the control substrate on which the contact electrodes are formed. It is preferable for the second insulating layer to be made of the same material as the first insulating layer described above. The second insulating layer according to the present invention is preferably made of a transparent material due to the structure of the T-shaped light-emitting rod.

As shown in FIG. 3B, the coupling recess is formed by a patterning process of the second insulating layer, is formed in such a shape that the T-shaped light-emitting rod is not coupled in the forward or reverse direction but can be advantageously aligned in the lateral direction, and is formed so as to have a depth sufficient for at least half of the T-shaped light-emitting rod to be coupled in the lateral direction. This facilitates coupling of the T-shaped light-emitting rod to the coupling recess and prevents the T-shaped light-emitting rod from being arbitrarily separated from the coupling recess or from being easily separated from the coupling recess even when certain force is applied thereto.

That is, a coupling recess is patterned on a second insulating layer on which the contact electrodes are formed, and the T-shaped light-emitting rod is laid and coupled to the coupling recess in the lateral direction such that the T-shaped light-emitting rod is aligned (FIG. 3C).

Here, since the T-shaped light-emitting rod is aligned according to the position and array of the coupling recess, selective array and fixation of the T-shaped light-emitting rod at a specific position on the control substrate are easily performed.

In the embodiment of the present invention, the T-shaped light-emitting rods manufactured according to the present invention are scattered on the control substrate having the coupling recesses formed therein such that the upper surface of the control substrate is completely covered with the T-shaped light-emitting rods, and the control substrate is stirred with force such that the T-shaped light-emitting rods are not separated from the coupling recesses, whereby the T-shaped light-emitting rods naturally enter the coupling recesses in the lateral direction and are coupled thereto.

At this time, the entirety of the control substrate may be immersed in a dispersion to facilitate stirring, and the T-shaped light-emitting rods are aligned by scattering the T-shaped light-emitting rods until the T-shaped light-emitting rods enter all of the coupling recesses and removing the rods that have not entered the coupling recesses, which is repeated several times. When removing the T-shaped light-emitting rods that have not entered the coupling recesses, it is preferable to form each of coupling recesses so as to have a depth slightly greater than the depth of a corresponding one of the T-shaped light-emitting rods in the lateral direction in order to prevent the T-shaped light-emitting rods in the coupling recesses from being separated from the coupling recesses.

In addition, according to the embodiment of the present invention, coupling surfaces of the T-shaped light-emitting rod and the coupling recess may be surface-modified so as to be mutually stably coupled to each other.

For example, when the first conductive semiconductor layer, the active layer, and the second conductive semiconductor layer of the T-shaped light-emitting rod are exposed or are surrounded by the first insulating layer, the surfaces thereof are surface-modified such that the T-shaped light-emitting rod can be coupled and stably fixed to the coupling recess formed by the second insulating layer, whereby the T-shaped light-emitting rod can be more securely coupled to the coupling recess.

In the embodiment of the present invention, the surfaces of the first conductive semiconductor layer, the active layer, the second conductive semiconductor layer, the first insulating layer, and the second insulating layer may be subjected to plasma surface treatment or corona treatment such that coupling surfaces thereof are in more stable contact with each other, or the coupling surfaces may have a hydroxyl group (—OH) or a coupling linker while the other surfaces may not have the same in order to further increase coupling force. The coupling linker may include two or more functional groups, and an oxide, aminopropyltriethoxysilane reacting therewith, or the like may be used.

In the step of connecting the first electrode and the second electrode to the contact electrodes on the control substrate, the second insulating layer is etched to expose electrode contact portions of the first conductive semiconductor layer and the second conductive semiconductor layer while the first conductive semiconductor layer and the second conductive semiconductor layer are insulated from each other (FIG. 3D), and the first electrode and the second electrode are formed and connected to the contact electrodes on the control substrate (FIGS. 3E and 5).

Here, when the first insulating layer is formed on the T-shaped light-emitting rod, the first insulating layer and the second insulating layer are etched to expose the electrode contact portions.

The first insulating layer and the second insulating layer are etched so as to correspond to the positions of the contact electrodes formed on the control substrate, the electrode contact portions of the first conductive semiconductor layer and the second conductive semiconductor layer that expose the contact electrodes formed on the control substrate are formed, the first electrode and the second electrode are formed on the electrode contact portions, respectively, and the first electrode and the second electrode are connected to the contact electrodes on the control substrate, respectively.

This is accomplished by mask patterning using a known mask pattern, etching, and electrode deposition.

FIG. 5 is a schematic view showing the state in which the T-shaped light-emitting rod according to the embodiment of FIGS. 4A, 4B, 4C, 4D, and 4E is aligned in the coupling recess, the first electrode and the second electrode are connected to the contact electrodes, and the T-shaped light-emitting rod is aligned on the control substrate and is electrically connected thereto according to the process described above.

Meanwhile, FIGS. 6A, 6B, 6C, 6D, and 6E show another embodiment of the present invention, wherein the step of laying and aligning the T-shaped light-emitting rod on the control substrate in the lateral direction includes a first process of forming a second insulating layer on the control substrate including the electrodes, forming a first coupling recess in the second insulating layer such that a first T-shaped light-emitting rod can be aligned in the lateral direction, and aligning the first T-shaped light-emitting rod in the first coupling recess (FIG. 6A), a second process of shielding the first T-shaped light-emitting rod with the second insulating layer, forming a second coupling recess in an adjacent region, and aligning a second T-shaped light-emitting rod having a different active layer from the first T-shaped light-emitting rod in the second coupling recess (FIG. 6B), and a third process of shielding the second T-shaped light-emitting rod with the second insulating layer, forming a third coupling recess in an adjacent region, and aligning a third T-shaped light-emitting rod having a different active layer from the first and second T-shaped light-emitting rods in the third coupling recess (FIG. 6C).

Subsequently, the second insulating layer is etched to simultaneously expose electrode contact portions of first conductive semiconductor layers and second conductive semiconductor layers of the first, second, and third T-shaped light-emitting rods while insulating the same from each other (FIG. 6D), and the first electrode and the second electrode are formed and connected to contact electrodes on the control substrate (FIG. 6E).

The previous embodiment relates to a method of aligning a T-shaped light-emitting rod having a single emission wavelength on the control substrate, and the present embodiment relates to a method of aligning a T-shaped light-emitting rod having two or more emission wavelengths (red, green, and blue) on the control substrate.

Pluralities of first, second, and third T-shaped light-emitting rods having different emission wavelengths are simultaneously aligned on the control substrate by the first process, the second process, and the third process, respectively, the second insulating layer (or the first insulating layer and the second insulating layer) is etched to expose the electrode contact portions of the first conductive semiconductor layer and the second conductive semiconductor layer formed on each T-shaped light-emitting rod and the contact electrodes on the control substrate, and the first electrode and the second electrode are formed and electrically connected to the contact electrodes on the control substrate.

For example, a plurality of first coupling recesses for forming T-shaped light-emitting rods each having a red emission wavelength is formed, all of the T-shaped light-emitting rods each having the red emission wavelength are aligned therein, the same is shielded by a second insulating layer, a plurality of second coupling recesses for forming T-shaped light-emitting rods each having a green emission wavelength is formed, all of the T-shaped light-emitting rods each having the green emission wavelength are aligned therein, the same is shielded by the second insulating layer, a plurality of third coupling recesses for forming T-shaped light-emitting rods each having a blue emission wavelength is formed, all of the T-shaped light-emitting rods each having the blue emission wavelength are aligned therein, and the second insulating layer is finally shielded.

Subsequently, electrode contact portions of first conductive semiconductor layers and second conductive semiconductor layers of all of the T-shaped light-emitting rods are formed for electrode formation, contact electrodes on the control substrate are exposed, and a first electrode and a second electrode are simultaneously formed at the electrode contact portions, whereby it is possible to provide a display apparatus having multiple emission wavelengths.

That is, coupling recesses according to respective emission wavelengths sequentially formed, T-shaped light-emitting rods having respective emission wavelengths are aligned therein, and electrodes are simultaneously formed, whereby alignment of the T-shaped light-emitting rods for implementation of a full-color display apparatus may be achieved quickly and simply.

In addition, according to the embodiment of the present invention, the T-shaped light-emitting rods and the coupling recesses may be mutually stably coupled to each other by surface modification of coupling surfaces thereof, as described above.

The first insulating layer and the second insulating layer are etched so as to correspond to the positions of the contact electrodes formed on the control substrate, the electrode contact of portions the first conductive semiconductor layer and the second conductive semiconductor layer that expose the contact electrodes formed on the control substrate are formed, the first electrode and the second electrode are formed on the electrode contact portions, respectively, and the first electrode and the second electrode are connected to the contact electrodes on the control substrate, respectively.

This process is accomplished by mask patterning using a mask pattern, etching, and electrode deposition.

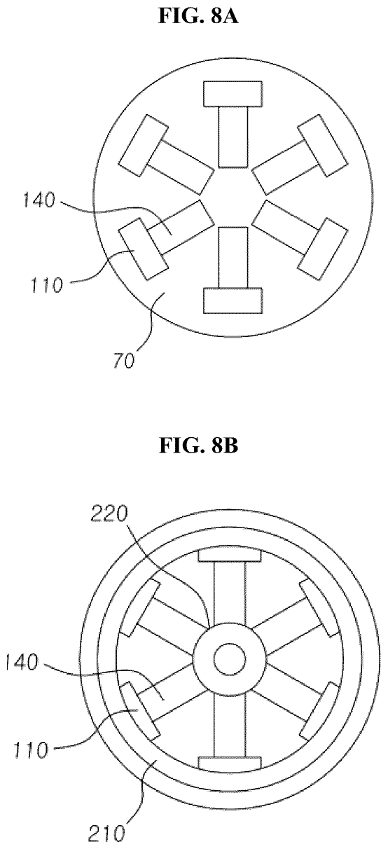

FIGS. 7A, 7B, 8A, 8B, and 9 are schematic views showing display apparatuses according to various embodiments of the present invention, wherein the first, second, and third T-shaped light-emitting rods may be aligned on the control substrate in a linear array in the same direction, may be aligned on the control substrate in a linear array in opposite directions (FIGS. 7A and 7B), or may be aligned radially on the control substrate (FIGS. 8A and 8B).

FIGS. 7A and 8A are schematic views showing alignment 4 the T-shaped light-emitting rods before electrodes are connected thereto when viewed from above, and FIGS. 7B and 8B are schematic views showing the state in which the electrodes are connected thereto.

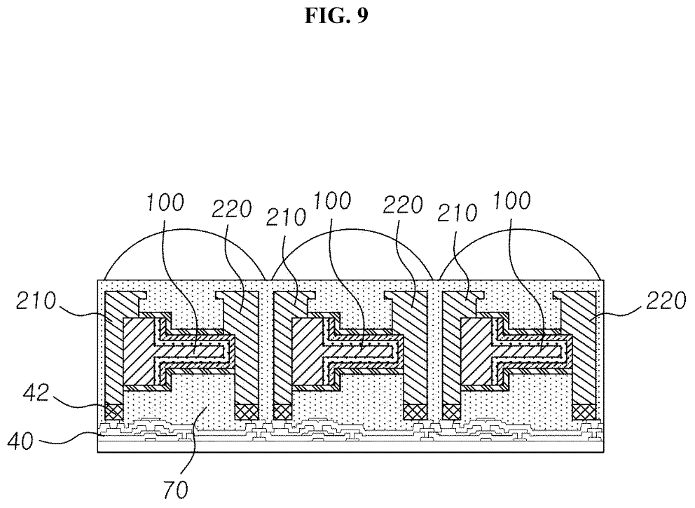

FIG. 9 shows a display apparatus in which a lens portion is further formed on a T-shaped light-emitting rod to induce diffusion of light, thereby providing softer light, as another embodiment. The formation of the lens portion may be achieved by forming a micro-lens pattern made of a transparent resin on the second insulating layer.

A display apparatus according to an embodiment of the present invention thus manufactured includes a control substrate including contact electrodes, an insulating layer (a second insulating layer) formed on the control substrate, the insulating layer including a coupling recess, a T-shaped light-emitting rod received in the coupling recess and laid and aligned in a lateral direction, the T-shaped light-emitting rod including a first conductive semiconductor layer, an active layer, and a second conductive semiconductor layer, and a first electrode connected to the first conductive semiconductor layer and a second electrode connected to the second conductive semiconductor layer, the first electrode and the second electrode being connected to the contact electrodes.

Here, a plurality of T-shaped light-emitting rods is aligned in a plurality of coupling recesses, respectively, and includes active layers having the same emission wavelength or different emission wavelengths, whereby single wavelength or full color implementation is possible.

As such, the present invention provides a display apparatus configured by forming a T-shaped light-emitting rod and aligning the same on a control substrate for display.

In particular, the present invention provides a display apparatus configured by manufacturing a T-shaped light-emitting rod, aligning the same on a control substrate in a lateral direction, and forming electrodes, wherein ultra-small T-shaped light-emitting rods may be easily aligned on the control substrate for display in large quantities, light emission efficiency is increased, and selective array and fixation of the T-shaped light-emitting rods at a specific position on the control substrate are easily performed.

1. A method of manufacturing a display apparatus, the method comprising:
forming a T-shaped light-emitting rod comprising a first conductive semiconductor layer, an active layer, and a second conductive semiconductor layer;
laying and aligning the T-shaped light-emitting rod on a control substrate in a lateral direction (├); and
forming a first electrode connected to the first conductive semiconductor layer of the aligned T-shaped light-emitting rod, forming a second electrode connected to the second conductive semiconductor layer, and connecting the first electrode and the second electrode to contact electrodes on the control substrate, respectively,
wherein the step of laying and aligning the T-shaped light-emitting rod on the control substrate in the lateral direction comprises:
a first process of forming a second insulating layer on the control substrate comprising the contact electrodes, forming a first coupling recess in the second insulating layer such that a first T-shaped light-emitting rod can be aligned in the lateral direction, and aligning the first T-shaped light-emitting rod in the first coupling recess,
a second process of shielding the first T-shaped light-emitting rod with the second insulating layer, forming a second coupling recess in an adjacent region, and aligning a second T-shaped light-emitting rod having a different active layer from the first T-shaped light-emitting rod in the second coupling recess, and
a third process of shielding the second T-shaped light-emitting rod with the second insulating layer, forming a third coupling recess in an adjacent region, and aligning a third T-shaped light-emitting rod having a different active layer from the first and second T-shaped light-emitting rods in the third coupling recess, whereby
pluralities of first, second, and third T-shaped light-emitting rods having different emission wavelengths are simultaneously aligned on the control substrate by the first process, the second process, and the third process, respectively.

2. The method according to claim 1, wherein the step of forming the T-shaped light-emitting rod comprises:
forming a sacrificial layer on a growth substrate;
forming a first conductive semiconductor layer on the sacrificial layer;
forming a rod pattern through selective etching or selective growth by patterning of the first conductive semiconductor layer;
forming an active layer so as to surround the first conductive semiconductor layer and the rod pattern;
forming a second conductive semiconductor layer so as to surround the active layer;
mesa-etching the second conductive semiconductor layer, the active layer, and the first conductive semiconductor layer between the rod pattern; and
removing the sacrificial layer and separating the first conductive semiconductor layer from the growth substrate to form a T-shaped light-emitting rod.

3. The method according to claim 2, wherein the step of forming the rod pattern is performed by a mask patterning process of the first conductive semiconductor layer.

4. The method according to claim 3, wherein the mask patterning process comprises:
forming a mask pattern on the first conductive semiconductor layer; and
forming the rod pattern in a top-down manner using the same as an etching mask.

5. The method according to claim 3, wherein the mask patterning process comprises:
forming a mask pattern on the first conductive semiconductor layer; and
forming the rod pattern in a bottom-up manner using the same as a deposition mask.

6. The method according to claim 2, further comprising:
forming a first insulating layer on the sacrificial layer and the second conductive semiconductor layer after the mesa-etching step; and
etching the first insulating layer on the sacrificial layer.

7. The method according to claim 1, wherein the step of forming the T-shaped light-emitting rod comprises:
forming a sacrificial layer on a growth substrate;
forming a first conductive semiconductor layer on the sacrificial layer;
forming an active layer on the first conductive semiconductor layer;
forming a second conductive semiconductor layer on the active layer;
forming a rod pattern comprising the second conductive semiconductor layer and the active layer by a mask patterning process;
mesa-etching the first conductive semiconductor layer between the rod pattern; and
removing the sacrificial layer and separating the first conductive semiconductor layer from the growth substrate to form a T-shaped light-emitting rod.

8. The method according to claim 7, further comprising:
forming a first insulating layer on the sacrificial layer and the rod pattern after the mesa-etching step; and
etching the first insulating layer formed on the sacrificial layer.

9. (canceled)

10. (canceled)

11. (canceled)

12. (canceled)

13. The method according to claim 1, wherein the step of connecting the first electrode and the second electrode to the contact electrodes on the control substrate, respectively, comprises:
etching the second insulating layer to simultaneously expose electrode contact portions of first conductive semiconductor layers and second conductive semiconductor layers of the first, second, and third T-shaped light-emitting rods and insulating the first conductive semiconductor layer and the second conductive semiconductor layer from each other; and
forming the first electrode and the second electrode and connecting the first electrode and the second electrode to the contact electrodes on the control substrate, respectively.

14. The method according to claim 1, wherein the first, second, and third T-shaped light-emitting rods are configured:
to be aligned on the control substrate in a linear array in the same direction;
to be aligned on the control substrate in a linear array in opposite directions; or
to be aligned radially on the control substrate.

15. The method according to claim 1, wherein coupling surfaces of the T-shaped light-emitting rod and the coupling recess are surface-modified so as to be mutually stably coupled to each other.

16. (canceled)

17. (canceled)

18. (canceled)

19. (canceled)
